(19) United States
(12) Patent Application Publication
(10) Pub. No.: US 2025/0226129 A1
(43) Pub. Date: Jul. 10, 2025

(54) CABLE AND DAMAGE DETECTION DEVICE

(71) Applicant: Proterial, Ltd., Tokyo (JP)

(72) Inventors: Hirotaka ESHIMA, Tokyo (JP); Yoshikazu HAYAKAWA, Ibaraki (JP); Tomoyuki MURAYAMA, Tokyo (JP); Takahiro FUTATSUMORI, Mito-shi (JP)

(73) Assignee: Proterial, Ltd., Tokyo (JP)

(21) Appl. No.: 18/978,576

(22) Filed: Dec. 12, 2024

(30) Foreign Application Priority Data
Jan. 10, 2024 (JP) 2024-002102

(51) Int. Cl. H01B 7/00; G01R 31/58; H01B 7/18

(52) U.S. Cl. CPC H01B 7/0045; G01R 31/58; H01B 7/1855

(57) ABSTRACT

A cable includes a wire bundle composed of a plurality of wires bundled together, a binder member spirally wound around an outer circumference of the wire bundle, and a sheath covering the binder member. The binder member includes a base material composed of a band-shaped insulating material, and a planar conductor provided on one side of the base material along a longitudinal direction of the base material. The binder member is overlappedly wound around the outer circumference of the wire bundle in such a manner that ends in a width direction of the base material overlap each other. A damage detection device includes the binder member and a damage detection circuit that detects an occurrence of damage when the planar conductor is damaged.

### CROSS-REFERENCE TO RELATED APPLICATIONS

The present patent application claims the priority of Japanese patent application No. 2024-002102 filed on Jan. 10, 2024, the entire contents of which are incorporated herein by reference.

### TECHNICAL FIELD

The present invention relates to a cable and a damage detection device for detecting damage to the cable.

### BACKGROUND OF THE INVENTION

Conventionally, there are cables with multiple wires that can detect signs (specifically, predictive signs) of an abnormality such as wire breakage (i.e., disconnection) before it occurs (see, for example, Patent Literature 1).

In the first embodiment of the invention described in Patent Literature 1, a detection line is located in the center of the cable, and a plurality of wires that are to be subjected to detecting signs of damage are located around the detection line. The detection line has lower bending resistance than the surrounding wires, and is more likely to break due to metal fatigue when subjected to bending. When an inspection signal including an AC component is input to the detection line by the abnormality detection device and a change of more than a reference value occurs in the characteristic impedance of the detection line and a break is detected in a detection line conductor, the device notifies the outside that there are signs of a break in the wires.

In the second and third embodiments of the invention described in Patent Literature 1, in addition to the above detection line, an outer detection layer is provided to detect damage to the wires caused by external damage when a sudden shock is applied from outside the cable. In the second embodiment, the outer detection layer is a conductive tape comprising a conductive material, and the conductive tape is spirally wrapped around the further outer circumference of the tape layer which is composed of an insulating tape body wrapped around the outer circumference of the wire group. In the third embodiment, the outer detection layer is a laminated tape composed of conductive coating layers formed on both sides of an insulating base material, and this laminated tape is spirally wrapped around the outer circumference of the wire group. The abnormality detection device also notifies the outside when the characteristic impedance of the conductive tape or the laminated tape changes by more than the reference value.
Citation List Patent Literature 1: JP7151754B

### SUMMARY OF THE INVENTION

When the conductive tape is spirally wound around the outer circumference of the tape layer, as in the second embodiment of the invention described in Patent Literature 1, it is necessary to wind the conductive tape around the outer circumference of the tape layer after winding the tape body that constitutes the tape layer at the time of cable manufacturing, which increases the man-hour requirement. In addition, when using the laminated tape with the conductive coating layers formed on both sides of the insulating base material, as in the third embodiment of the invention described in Patent Literature 1, the cable is repeatedly bent during use, causing the laminated tape to shift position in a cable longitudinal direction. If the conductive coating layer on one side of the base material contacts with the conductive coating layer on the other side of the base material in a part of the longitudinal direction of the cable, the conductive coating layer cannot be detected even if breakage occurs in any of the conductive coating layers in this part, resulting in a detection failure (detection omission).

It is, therefore, an object of the present invention to provide a cable capable of reducing the occurrence of detection omissions and false detections while suppressing the increase in man-hours during manufacturing and a damage detection device using such a cable.

To solve the problems described above, the invention provides a cable, comprising a wire bundle comprising a plurality of wires bundled together; a binder member spirally wound around an outer circumference of the wire bundle; and a sheath covering the binder member, wherein the binder member includes a base material comprising a band-shaped insulating material, and a planar conductor provided on one side of the base material along a longitudinal direction of the base material, and wherein the binder member is overlappedly wound around the outer circumference of the wire bundle in such a manner that ends in a width direction of the base material overlap each other.

To solve the problems described above, another aspect of the invention provides a damage detection device, comprising a binder member spirally wound around an outer circumference of a wire bundle comprising a plurality of wires bundled together and a base material comprising a band-shaped insulating material and a planar conductor provided on one side of the base material along a longitudinal direction of the base material; and a damage detection circuit that detects an occurrence of damage when the planar conductor is damaged.

### Effects of the Invention

According to the invention, it is possible to provide a cable capable of reducing the occurrence of detection omissions and false detections while suppressing the increase in man-hours during manufacturing and a damage detection device using such a cable.

### BRIEF DESCRIPTION OF DRAWINGS

FIG. 1 is a cross-sectional view of a cable in the first embodiment of the invention.

FIG. 2 is an explanatory diagram showing a configuration of a wire bundle.

FIG. 3 is a perspective view showing a binder member as a single unit.

FIG. 4 is a cross-sectional view showing the binder member in a spiral wound state.

FIG. 5A is a circuit diagram showing an example configuration of a damage detection device that detects cable damage.

FIG. 5B is a cross-sectional view showing an example configuration of a linear conductor.

FIG. 6 is a cross-sectional view of a cable in a comparative example.

FIG. 7A is a perspective view showing the binder member in a modified example of the first embodiment as a single unit.

FIG. 7B is a cross-sectional view of the binder member in the modified example.

FIG. 8 is a cross-sectional view of the cable in the second embodiment of the invention.

FIG. 9A is a cross-sectional view of a cable in the third embodiment of the invention.

FIG. 9B is a cross-sectional view of a vulnerable wire in the cable in the third embodiment.

FIG. 10 is a circuit diagram showing an example of a configuration of a damage detection device in the third embodiment.

### DETAILED DESCRIPTION OF THE INVENTION

### Embodiments

### First Embodiment

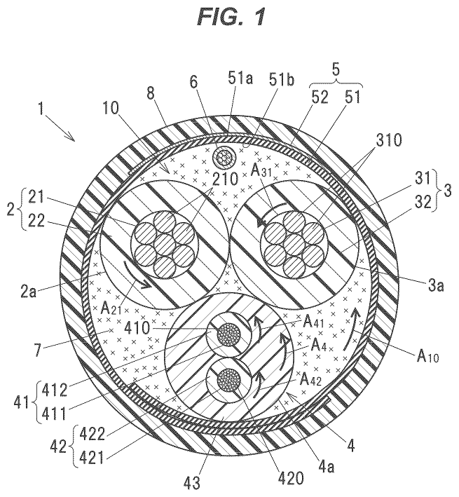

FIG. 1 is a cross-sectional view of a cable 1 in the first embodiment of the invention. The cable 1 comprises a wire bundle 10 consisting of a plurality of wires 2 to 4 bundled together, a binder member 5 spirally wound around an outer circumference of the wire bundle 10, a linear conductor 6 and fillers 7 covered by the binder member 5 together with the wire bundle 10, and a sheath 8 covering the binder member 5.

In the present embodiment, of the plurality of wires 2 to 4, the first and second wires 2 and 3 are power lines for supplying operating power to a target device. The third wire 4 is a multi-core wire consisting of a pair of signal wires 41 and 42 covered by an inner sheath 43. One ends of the first to third wires 2 to 4 of the cable 1 are connected to unsprung members of a vehicle, and the other ends of the first to third wires 2 to 4 is connected to a control device located on a vehicle body side, which is a sprung member. The target device as the unsprung member that is powered by the first and second wires 2 and 3 is, for example, an electric parking brake device that locks the wheels when the vehicle stops. A pair of signal wires 41 and 42 of the third wire 4 are connected to a wheel speed sensor that detects the rotation speed of the wheel, for example, and transmits output signals of the wheel speed sensor. The cable 1 is repeatedly bent in part of its longitudinal direction as the suspension spring expands and contracts during vehicle travel.

The first wire 2 is an insulated electric wire in which a conductor 21 is covered with an insulator 22. The second wire 3 is an insulated electric wire in which a conductor 31 is covered with an insulator 32. The conductors 21 and 31 are stranded wires consisting of a plurality of strands 210 and 310 made of a good conductive metal such as copper twisted together, respectively. The pair of signal wires 41, 42 of the third wire 4 are insulated electric wires in which conductors 411, 421 are covered with insulators 412, 422, respectively. The conductors 411, 421 are stranded wires consisting of a plurality of strands 410, 420 made of a good conductive metal such as copper twisted together, respectively. The insulators 22, 32 of the first and second wires 2, 3, and the insulators 412, 422 of the pair of signal wires 41, 42 of the third wire 4 are made of fluororesin, for example.

The signal wires 41, 42 of the third wire 4 each have a smaller outer diameter than the first wire 2 and the second wire 3. The respective outer diameters of the signal wires 41, 42 are equal to or less than half the outer diameters of the first wire 2 and the second wire 3. The signal wires 41 and 42 of the third wire 4 are a type of small-diameter wire, and the first wire 2 and second wire 3 are a type of large-diameter wire. Although the wire bundle 10 is configured to include one multi-core wire (the third wire 4), a plurality of wires constituting the wire bundle may include a plurality of multi-core wires. The plurality of wires comprising the wire bundle may not include a multi-core wire.

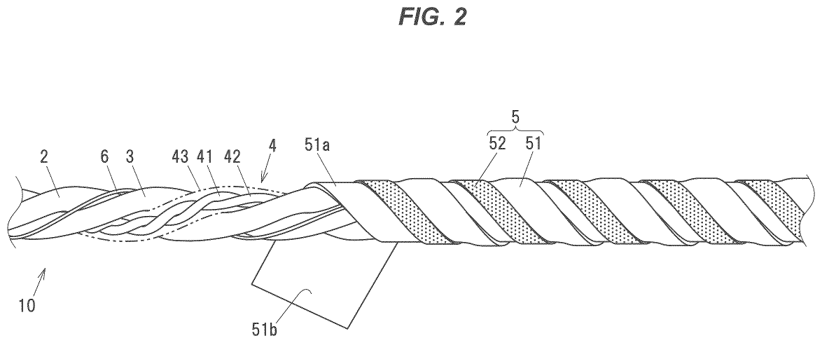

FIG. 2 is an explanatory diagram showing the configuration of the wire bundle 10 and the binder member 5. In FIG. 2, the fillers 7 and the sheath 8 are omitted, and the wire bundle 10 and the binder member 5 are shown viewed from a radial direction of the cable 1. In FIG. 2, the contour of an inner sheath 43 of the third wire 4 is shown as a virtual line (two dotted lines) in a part of the longitudinal direction of the wire bundle 10, and a pair of signal wires 41, 42 are shown as solid lines.

As shown in FIG. 2, the first to third wires 2 to 4 are twisted together, and the pair of signal wires 41, 42 of the third wire 4 are further twisted together inside the inner sheath 43 to form a twisted pair wire. In FIG. 1, the twisting direction of the first to third wires 2 to 4 is indicated by arrow A₁₀, and the twisting direction of the pair of signal wires 41, 42 in the multi-core wire 4 is indicated by arrow A₄. As shown in FIGS. 1 and 2, the twisting direction of the first to third wires 2 to 4 and the twisting direction of the pair of signal wires 41, 42 in the longitudinal direction of the cable 1 are the same in the present embodiment.

In FIG. 1, the twisting direction of the plurality of strands 210 in the conductor 21 of the first wire 2, the twisting direction of the plurality of strands 310 in the conductor 31 of the second wire 3, and the twisting direction of the plurality of strands 410, 420 of the pair of signal wires 41, 42 in the multi-core wire 4 are indicated by arrows A₂₁, A₃₁, A₄₁, A₄₂, respectively. The twisting direction of these strands 210, 310, 410, 420 is the same as the twisting direction of the first to third wires 2 to 4 and the twisting direction of the pair of signal wires 41, 42. This makes it difficult for the twists of the first to third wires 2 to 4 to unravel.

The filler 7 is made of a fibrous material such as aramid fiber or Kevlar (registered trademark), for example, and is disposed between the first to third wires 2 to 4 and the binder member 5. The fillers 7 make the shape of the binder member 5 in a cross-section perpendicular to the longitudinal direction of the cable 1 close to a circle. In other words, the fillers 7 make the shape of the binder member 5 in the cross-section perpendicular to the longitudinal direction of the wire bundle 10 circular. This allows the cable 1 to flexibly bend in any direction.

The outer diameter of the first wire 2 is the same as the outer diameter of the second wire 3. The outer diameter of the third wire 4 is the same as the outer diameters of the first wire 2 and the second wire 3. Specifically, the outer diameter of the third wire 4 is 95% or more and 105% or less of the outer diameters of the first wire 2 and the second wire 3. This dimensional relationship contributes to circularizing the shape of the binder member 5 in a cross-section perpendicular to the longitudinal direction of the wire bundle 10.

In the example shown in FIG. 1, a portion of outer circumferential surfaces 2a, 3a, 4a of the respective first to third wires 2 to 4 are in contact with each other and a portion of the outer circumferential surfaces 2a, 3a, 4a of the respective first to third wires 2 to 4 are in contact with the binder member 5, but the outer circumferential surfaces 2a, 3a, 4a of the respective first to third wires 2 to 4 may not be in contact with each other, and the outer circumferential surfaces 2a, 3a, 4a of the respective first to third wires 2 to 4 may not be in contact with the binder member 5.

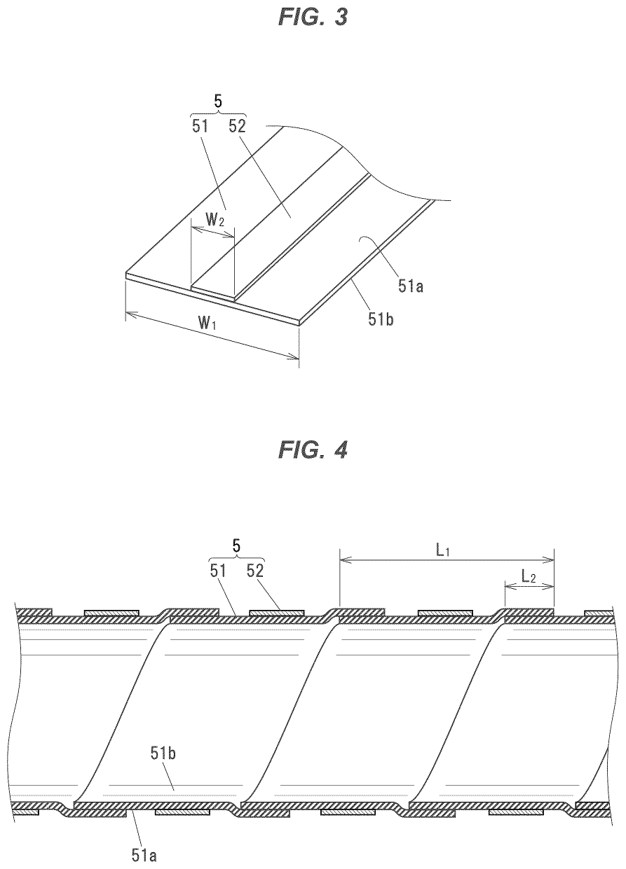

FIG. 3 is a perspective view of the binder member 5 as a single unit. FIG. 4 is a cross-sectional view showing the binder member 5 in a spirally wound state. The binder member 5 has a base material 51 made of a flexible band-shaped insulator and a planar conductor 52 provided on one side 51a of the base material 51 along the longitudinal direction of the base material 51. The other side 51b of the base material 51, which is the back side of the one side 51a of the base material 51, is not provided with a conductor. In other words, the planar conductor 52 is provided only on the one side 51a of the base material 51. Since the planar conductor 52 is integrated with the base material 51, the pitch of the base material 51 in the longitudinal direction of the cable 1 and the pitch of the planar conductor 52 in the longitudinal direction of the cable 1 are the same when the binder member 5 is spirally wound.

In the present embodiment, the planar conductor 52 is formed by vapor deposition on the one side 51a of the base material 51. The base material 51 is a strip of, for example, non-woven fabric, paper, or resin such as polyester. The planar conductor 52 is mainly made of a good conductive metal such as copper, silver, or aluminum. The fact that the planar conductor 52 is provided on the one side 51a of the base material 51 ensures the strength of the planar conductor 52 and prevents the planar conductor 52 from being excessively easy to break.

Although the thickness of the planar conductor 52 is thinner than the thickness of the base material 51 in the present embodiment, it is not limited to this, and the planar conductor 52 may be thicker than the base material 51. If the thickness of the planar conductor 52 is thinner than the thickness of the base material 51, the occurrence of external damage due to stone chipping or other causes and wear of the sheath 8 can be sensitively detected. If the planar conductor 52 is thicker than the base material 51, it is easier to prevent the planar conductor 52 from breaking due to friction with the sheath 8.

In FIG. 3, a width of the base material 51 in the shortitudinal direction of the binder member 5 is shown by W₁ and a width of the planar conductor 52 is shown by W₂. W₂ is narrower than W₁ and the planar conductor 52 is formed in the range excluding both ends of the base material 51 in the width direction. The desired range of a ratio of W₂ to W₁ depends on the thickness of the planar conductor 52 and the strength of the base material 51. For example, it is 10% or more and 30% or less. However, it is not limited to this, and the planar conductor 52 may be formed on the entire one side 51a of the base material 51.

The binder member 5 is overlappedly wound around the outer circumference of the wire bundle 10 in such a manner that the width-directional ends of the base material 51 overlap each other in the radial direction of the cable 1. In the present embodiment, the width-directional ends of the base material 51 overlap each other and are in contact with each other. More specifically, the one side 51a of the edge on one side of the base material 51 in the width direction and the other side 51b of the edge on the other side of the base material 51 in the width direction overlap and contact each other in the thickness direction of the base material 51. In the longitudinal direction of the cable 1 (right and left direction in FIG. 4), the ratio of an overlap length L₂ at the edge in the width direction of the base material 51 to a length L₁ of the base material 51 for one turn is for example 10% or more and 40% or less. In the overlapping portion of the binder member 5, a part of the other side 51b of the base material 51 may overlap with the planar conductor 52. In the present invention, there is no portion in the longitudinal direction of the cable 1 where the planar conductors 52 overlap each other while contacting each other. However, in the present invention, there may be portions in the longitudinal direction of the cable 1 where the planar conductors 52 overlap each other without contacting each other due to the presence of the base material 51.

In FIG. 2, the planar conductor 52 of the binder member 5 is shown in gray. As shown in FIGS. 1 and 2, the binder member 5 is spirally wound around the outer circumference of the wire bundle 10 in such a manner that the one side 51a of the base material 51 with the planar conductor 52 is on the outside, and in such a manner than the other side 51b of the base material 51 presses the first to third wires 2 to 4 toward the center of the cable 1. The planar conductor 52 is in contact with the sheath 8 on the outside of the base material 51.

The sheath 8 is made of urethane resin, such as thermoplastic polyurethane, and is extruded around the outer circumference of the binder member 5. The binder member 5 covers the entire circumference of the wire bundle 10 in cross-sectional view. This prevents the liquid thermoplastic resin forming the sheath 8 from entering between the first to third wires 2 to 4 during the molding of the sheath 8.

The cable 1 constructed as described above may be subjected to the external damage due to impact by, for example, chipping during vehicle driving, or the sheath 8 may be severely abraded by friction with the outside. When the cable 1 is damaged by such external damage or wear, the occurrence of damage is detected by the damage detection device described below.

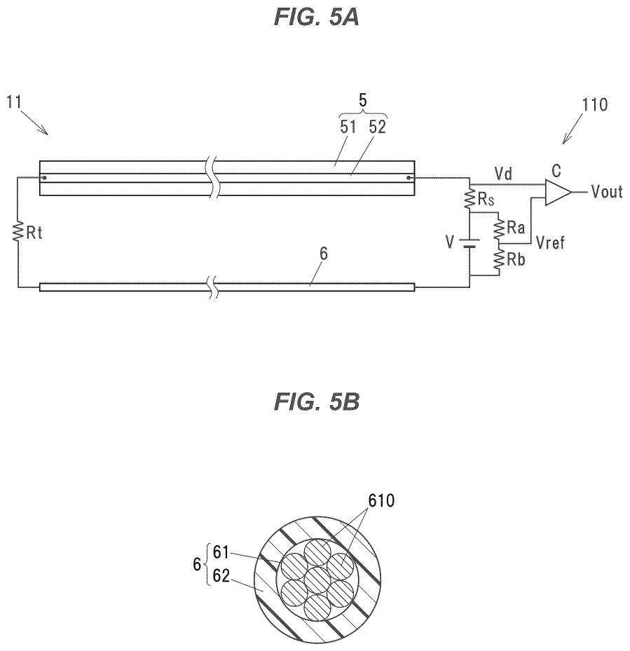

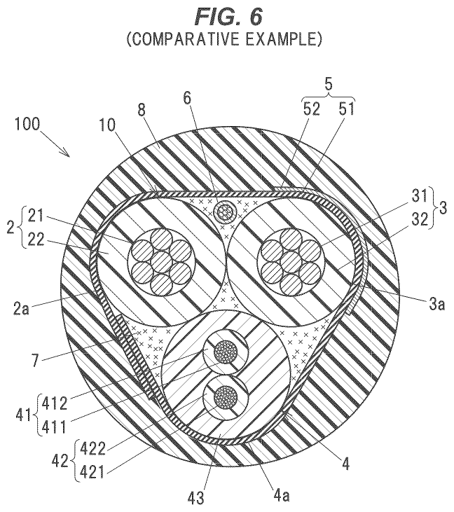

FIG. 5A is a circuit diagram showing an example configuration of the damage detection device 11 that detects damage to the cable 1. FIG. 5B is a cross-sectional view showing an example configuration of the linear conductor 6. The damage detection device 11 includes the binder member 5 and the linear conductor 6 as components and is configured to include a damage detection circuit 110 that electrically detects the occurrence of damage in the cable 1.

The linear conductor 6 is an insulated electric wire having a conductor 61 and an insulator 62 covering the conductor 61, as shown in FIG. 5B. In the example shown in FIG. 5B, the conductor 61 is a stranded wire consisting of a plurality of strands 610 twisted together, but the conductor 61 may be a single wire. The insulator 62 may be omitted and the linear conductor 6 may be an uncoated wire (bare wire).

The linear conductor 6 is placed inside the binder member 5 together with the first to third wires 2 to 4, and the conductor 61 of the linear conductor 6 is electrically connected to the planar conductor 52 of the binder member 5 at one terminal in the longitudinal direction of the cable 1. In the present embodiment, this terminal is a vehicle unsprung side end. The example shown in FIG. 5A shows a case in which the planar conductor 52 and the linear conductor 6 are connected by a termination resistor Rt. However, this is not limited to this case, and the conductor 61 of the linear conductor 6 may be directly connected to the planar conductor 52 of the binder member 5 and short-circuit them.

The linear conductor 6 has a lower bending endurance than the first to third wires 2 to 4, and when the cable 1 is repeatedly bent, it breaks before any of the first to third wires 2 to 4 break. The conductor cross-sectional area of the conductor 61 of the linear conductor 6 is smaller than the conductor cross-sectional area of the conductor 21 of the first wire 2, the conductor 31 of the second wire 3, and the conductors 411 and 421 of signal wires 41 and 42 of the third wire 4, respectively.

In the present embodiment, as shown in FIG. 1, the linear conductor 6 is placed between the first and second wires 2 and 3 and the binder member 5. However, the position of the linear conductor 6 is not limited to this, for example, the linear conductor 6 may be placed in the center of the cable 1 surrounded by the first to third wires 2 to 4. The linear conductor 6 may be spaced apart from the wire bundle 10 or may be in contact with the wire bundle 10 as shown in FIG. 1.

The damage detection circuit 110 is provided on the opposite side in the longitudinal direction of the cable 1 from the side where the planar conductor 52 of the binder member 5 and the conductor 61 of the linear conductor 6 are electrically connected and detects the occurrence of the damage when any of the planar conductor 52 or linear conductor 6 is damaged. When the damage detection circuit 110 detects the occurrence of damage, it outputs a damage detection signal to report the occurrence of damage. When this damage detection signal is output, the occurrence of damage to the cable 1 is reported to the driver, for example, by lighting a lamp on the instrument panel of the vehicle.

In the circuit example configuration of the damage detection circuit 110 shown in FIG. 5A, a shunt resistor Rs, the planar conductor 52, the termination resistor Rt, and the linear conductor 6 are connected in series between the + (positive) and − (negative) sides of a DC power supply V. The damage detection circuit 110 is also configured to include first and second reference resistors Ra, Rb connected in series between the + and − sides of the DC power supply V, and a comparator C, and a reference voltage Vref, which is the voltage obtained by resistively dividing the voltage of the DC power supply V by the first and second reference resistors Ra and Rb, and the detection voltage Vd, which is the voltage on the planar conductor 52 side of the shunt resistor Rs, are input to the comparator C.

If there is no breakage in any of the conductors 61 of the planar conductor 52 and the linear conductor 6, and a predetermined current is flowing in the series circuit consisting of the shunt resistor Rs, the planar conductor 52, the termination resistor Rt, and the linear conductor 6, a voltage drop corresponding to the magnitude of that current occurs in the shunt resistor Rs, and the detection voltage Vd becomes lower than the voltage of the DC power supply V. On the other hand, if any of the conductors 61 of the planar conductor 52 and the linear conductor 6 are disconnected, no current flows in this series circuit, and the detection voltage Vd becomes equal to the voltage of the DC power supply V.

The reference voltage Vref is adjusted to be a value between the detection voltage Vd when no breakage occurs in the conductors 61 of the planar conductor 52 and the linear conductor 6 and the detection voltage Vd. When a breakage occurs in any of the conductors 61 of the planar conductor 52 and the linear conductor 6, the output voltage Vout of comparator C changes. The output voltage Vout of comparator C is output from the damage detection circuit 110 as a damage detection signal indicating that damage has occurred in cable 1.

### Comparative Example

FIG. 6 is a cross-sectional view of a cable 100 in a comparative example. In FIG. 6, components that are common to the components of the cable 1 in the first embodiment are marked with the same symbols as those in FIG. 1, etc., and redundant explanations are omitted.

In the cable 100, the binder member 5 has a triangular shape with rounded corners in the cross-section of the cable 100. That is, at each corner of this triangular shape, the base material 51 of the binder member 5 is curved along the outer circumferential surfaces 2a, 3a, and 4a of the first wire 2, the second wire 3, and the third wire 4 with the curvature of the outer circumferential surface 2a, 3a, and 4a of these wires.

In this cable 100, compared to the cable 1 in the first embodiment, the planar conductor 52 of the binder member 5 is subjected to stress due to bending at a large curvature, and this stress causes the planar conductor 52 to break easily, and false detection of damage is likely to occur. Meanwhile, in the cable 1 in the first embodiment, the shape of the binder member 5 in the cross-section perpendicular to the longitudinal direction of the wire bundle 10 is circular, and the curvature of the base material 51 is smaller than that of the outer circumferential surfaces 2a, 3a, 4a of the first to third wires 2 to 4, so stress due to bending in the planar conductor 52 is less likely to occur and this prevents the occurrence of false detection.

### Effects of the First Embodiment

According to the first embodiment described above, the binder member 5 has the base material 51 and the planar conductor 52, and when the planar conductor 52 breaks, the occurrence of the break is detected by the damage detection circuit 110. This makes it possible to reduce the occurrence of false detection while suppressing the increase in man-hours during manufacturing, compared to, for example, when the binder tape and conductive tape are individually wound around the outer circumference of the wire bundle 10. In addition, since the planar conductors 52 are provided on only the one side 51a of the base material 51, the planar conductors 52 of different turns of the spirally wound binder member 5 do not come into contact with each other, thereby reducing the occurrence of detection omission. In addition, during the molding of the sheath 8, the liquid thermoplastic resin forming the sheath 8 can suppress the shifting of the planar conductors 52 with respect to the base material 51 from the desired position.

According to the first embodiment, even when the linear conductor 6 has a lower bending endurance than the first to third wires 2 to 4 and the linear conductor 6 breaks, the occurrence of the breakage is detected by the damage detection circuit 110. Therefore, in addition to sudden external damage due to the impact of chipping or the wear of the sheath 8, the breakage of the linear conductors 6 can detect the signs of breakage of the first to third wires 2 to 4 caused by metal fatigue due to repeated bending.

According to the first embodiment, the planar conductor 52 is provided on the one side 51a, which is the sheath 8 side surface in the base material 51, which prevents breakage of the planar conductor 52 due to wear caused by contact of the planar conductor 52 with the first to third wires 2 to 4.

### Modified Example of the First Embodiment

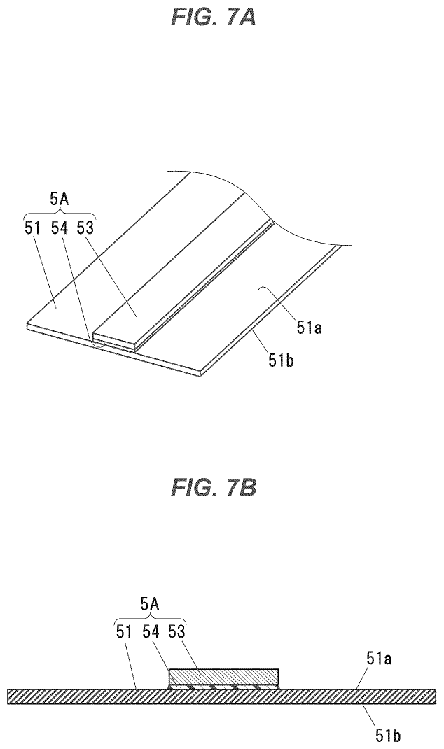

FIG. 7A is a perspective view of a binder member 5A in a modified example of the first embodiment as a single unit. FIG. 7B is a cross-sectional view of the binder member 5A in a cross-section perpendicular to the longitudinal direction of the binder member 5A. This binder member 5A is spirally wound around the outer circumference of the wire bundle 10 with the one side 51a of the base material 51 facing outward, in the same manner as the binder member 5 in the first embodiment.

In the first embodiment, the case in which the planar conductor 52 is formed by vapor deposition on the one side 51a of the base material 51 was described. The binder member 5A in the modified example has a base material 51 similar to the first embodiment and a planar conductor 53 provided by bonding to the one side 51a of the base material 51. The planar conductor 53 is a metal foil made of a good conductive metal such as copper, silver, or aluminum. A bonding layer 54 made of an adhesive is interposed between the base material 51 and the planar conductor 53. In other words, the planar conductor 53 is fixed to the base material 51 by the adhesive. The planar conductor 53 may be thicker than the base material 51 or thinner than the base material 51. The adhesive preferably has a melting point higher than the temperature of the liquid thermoplastic resin forming the sheath 8 at the time of molding the sheath 8. This can prevent the adhesive from softening or melting during the molding of the sheath 8, and can better prevent the planar conductor 52 from shifting from the desired position with respect to the base material 51.

Even when the binder member 5A in the modified example is used, the same effects as in the first embodiment can be obtained.

### Second Embodiment

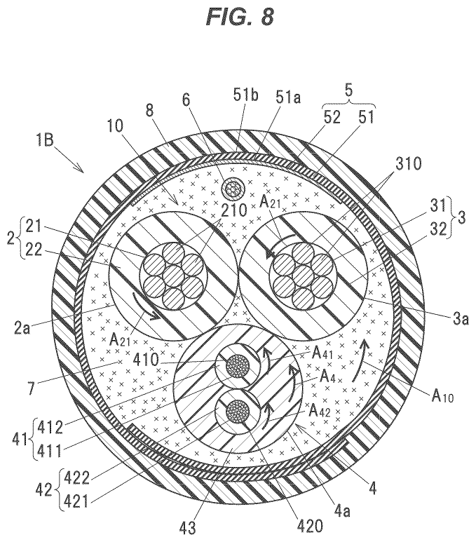

FIG. 8 is a cross-sectional view of a cable 1B in the second embodiment of the invention. In the first embodiment, the case in which the binder member 5 is wound around the outer circumference of the wire bundle 10 in such a manner that the one side 5a of the base material 51 on which the planar conductor 52 is formed is on the outside (the sheath 8 side) was described. In the second embodiment, the binder member 5 is wrapped around the outer circumference of the wire bundle 10 in such a manner that the one side 5a of the base material 51 on which the planar conductor 52 is formed is inside (wire bundle 10 side).

The fillers 7 are disposed between the planar conductor 52 and the first to third wires 2 to 4, and even when the cable 1B is bent, the planar conductor 52 and the first to third wires 2 to 4 are prevented from rubbing against each other. The shape of the binder member 5 in a cross-section perpendicular to the longitudinal direction of the wire bundle 10 is circularized by the fillers 7. The occurrence of damage in the cable 1B is detected by the damage detection circuit 110 described in the first embodiment. Depending on the strength of the planar conductor 52, a portion of the filler 7 may be removed, and the planar conductor 52 and the first to third wires 2 to 4 may be brought into contact. This allows the cable 1B to be made thinner in diameter.

Although the planar conductor 52 is formed by vapor deposition on the one side 5a of the base material 51 as an example, the binder member 5A in the modified example described with reference to FIGS. 7A and 7B may be used, and the binder member 5A may be wrapped around the outer circumference of the wire bundle 10 in such a manner that the one side 5a of the base material 51 becomes the inner side. By wrapping the binder member 5A around the outer circumference of the wire bundle 10 in such a manner that the one side 5a of the base material 51 is inside, the pressure of the resin during extrusion molding of the sheath 8 can prevent the adhesion of the planar conductor 53 of the binder member 5A from coming off.

This cable 1B in the second embodiment also makes it possible to reduce the occurrence of detection omissions and false detections while suppressing the increase in man-hours during manufacturing, as in the first embodiment.

### Third Embodiment

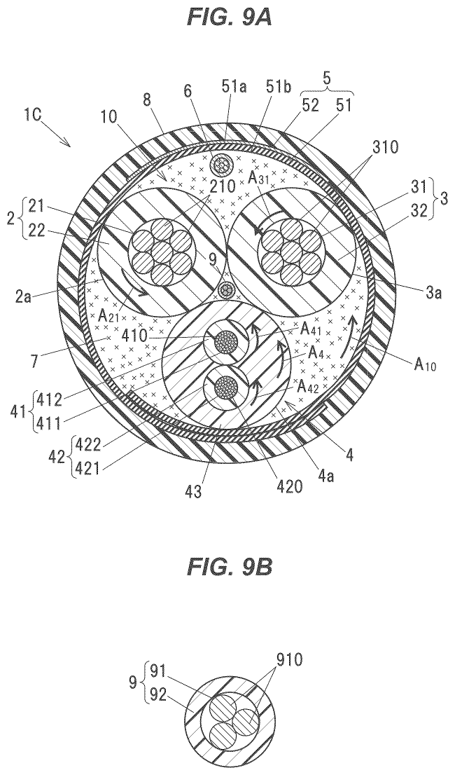

FIG. 9A is a cross-sectional view of a cable 1C in the third embodiment of the invention. The cable 1C in the third embodiment corresponds to the cable 1 in the first embodiment to which a vulnerable (weak, fragile, brittle) wire 9 is added, which has a lower bending endurance than the first to third wires 2 to 4 and is more prone to breakage. The vulnerable wire 9 is located in the center of the cable 1C surrounded by the first to third wires 2 to 4 and extends in the longitudinal direction of the cable 1C.

FIG. 9B is a cross-sectional view of the vulnerable wire 9. The vulnerable wire 9 is an insulated electric wire having a conductor 91 and an insulator 92 covering the conductor 91. The conductor 91 is a stranded wire consisting of a plurality of strands 910 twisted together, but it is not limited to this, and the conductor 91 may be a single wire. The insulator 92 may be omitted and the vulnerable wire 9 may be an uncoated wire (bare wire).

The vulnerable wire 9 is used to detect the signs of breakage of any of the first or third wires 2 to 4 before it occurs due to repeated bending of the cable 1C. In other words, in the present embodiment, the occurrence of damage such as sudden external damage due to chipping, etc. or wear of the sheath 8 is detected by the breakage of the planar conductor 52 of the binder member 5, and the signs of breakage due to metal fatigue of the conductors 21, 31, 411, 421 of the first to third wires 2 to 4 are detected by the breakage of the vulnerable wire 9. The thickness of the planar conductor 52 of the binder member 5 is thinner than the conductor diameter of the conductor 91 of the vulnerable wire 9. This allows sensitive detection of wear and external damage to the sheath 8.

In the cable 1C, instead of the binder member 5, the binder member 5A shown in FIGS. 7A and 7B, in which the planar conductor 53 is bonded to the one side 51a of the base material 51, may be used. In this case, the thickness of the planar conductor 53 of the binder member 5A is thinner than the conductor diameter of the conductor 91 of the vulnerable wire 9.

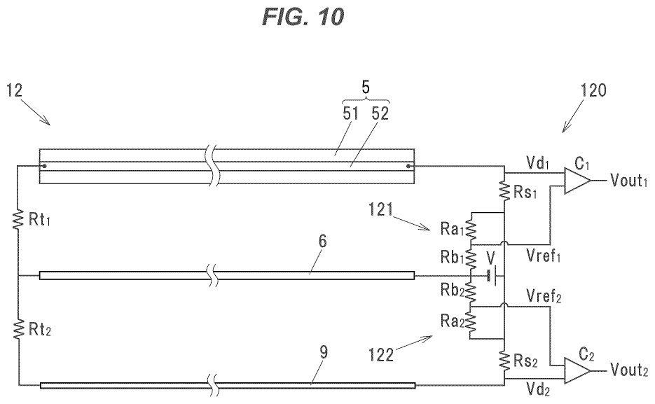

FIG. 10 is a circuit diagram showing an example configuration of a damage detection device 12 in the third embodiment. The damage detection device 12 includes the binder member 5, the vulnerable wire 9, and the linear conductor 6 of the cable 1C as components, and comprises a damage detection circuit 120. The damage detection circuit 120 has a first circuit section 121 for detecting breakage of the planar conductor 52 of the binder member 5, and a second circuit section 122 for detecting breakage of the conductor 91 of the vulnerable wire 9.

The first circuit section 121 of the damage detection circuit 120 has reference resistors Ra₁, Rb₁ that generate the reference voltage Vref₁ by resistively dividing the voltage of the DC power supply V, a shunt resistor Rs₁, and a comparator C₁ that compares the detection voltage Vd₁, which is the voltage on the planar conductor 52 side of the shunt resistor Rs₁, with the reference voltage Vref₁ and the output voltage Vout of the comparator C₁ changes when a breakage occurs in the planar conductor 52. The planar conductor 52 of the binder member 5 and the linear conductor 6 are electrically connected by a first termination resistor Rt₁ at a longitudinal terminal of the cable 1C, which is the end opposite to the damage detection circuit 120.

The second circuit section 122 of the damage detection circuit 120 has reference resistors Ra₂, Rb₂ that generate the reference voltage Vref₂ by resistively dividing the voltage of the DC power supply V, a shunt resistor Rs₂, and a comparator C₂ that compares the detection voltage Vd₂, which is the voltage on the vulnerable wire 9 side of the shunt resistor Rs₂, with the reference voltage Vref₂. The output voltage Vout₂ of the comparator C₂ changes when a breakage occurs in the conductor 91 of the vulnerable wire 9. The conductor 91 of the vulnerable wire 9 and the linear conductor 6 are electrically connected by a second termination resistor Rt₂ at a longitudinal terminal of the cable 1C, which is the end opposite to the damage detection circuit 120.

The output voltage Vout₁ of the comparator C₁ of the first circuit section 121 is output from the damage detection circuit 120 as a damage detection signal indicating that damage has occurred in the cable 1C. The output voltage Vout₂ of the comparator C₂ of the second circuit section 122 is output from the damage detection circuit 120 as a sign detection signal indicating that there are signs of breakage in the first to third wires 2 to 4 of the cable 1C. When the damage detection signal or the sign detection signal is output, the driver is informed, for example, by the lighting of a lamp on the instrument panel of the vehicle.

According to the third embodiment, it is possible to reduce the occurrence of detection omissions and false detections while suppressing the increase in man-hours during manufacturing, and to detect signs of wire breakage due to metal fatigue in the conductors 21, 31, 411, 421 of the first to third wires 2 to 4 by the vulnerable wire 9. In the first embodiment, the linear conductor 6 has a lower bending endurance than the first to third wires 2 to 4, but in the third embodiment, since the vulnerable wires 9 can detect the signs of breakage of the first to third wires 2 to 4, the bending endurance of the linear conductor 6 does not have to be lower than the bending endurance of the first to third wires 2 to 4. The vulnerable wire 9 does not necessarily have to be used for the first and third wires 2 to 4. The vulnerable wire 9 does not necessarily have to be located in the center of the cable 1C, and the vulnerable wire 9 may be placed between the first to third wires 2 to 4 and the binder member 5. In this case, the vulnerable wire 9 is twisted together with the first to third wires 2 to 4 and the linear conductor 6.

### Summary of Embodiments

Next, the technical concepts that can be grasped from the above embodiments and modified examples will be described with the aid of the code and symbols, etc. in the embodiments and modified examples. However, each code and symbols in the following description does not limit the constituent elements in the scope of claims to the members, etc. specifically shown in the embodiments.

According to the first feature, a cable 1, 1B, 1C includes a wire bundle 10 including a plurality of wires 2 to 4 bundled together, a binder member 5, 5A spirally wound around an outer circumference of the wire bundle 10, and a sheath 8 covering the binder member 5, 5A, wherein the binder member 5, 5A includes a base material 51 composed of a band-shaped insulating material, and a planar conductor 52, 53 provided on one side 51a of the base material 51 along a longitudinal direction of the base material 51, and wherein the binder member 5, 5A is overlappedly wound around the outer circumference of the wire bundle 10 in such a manner that ends in a width direction of the base material 51 overlap each other.

According to the second feature, in the cable 1, 1C as described in the first feature, the planar conductor 52, 53 is provided on a sheath 8 side (one side 51a) in the base material 51.

According to the third feature, in the cable 1, 1B, 1C as described in the first feature or the second feature, the binder member 5, 5A has a width W₂ of the planar conductor 52 in the width direction of the base material 51 narrower than a width W₁ of the base material 51, and wherein the ends in the width direction of the base material 51 overlap each other in contact.

According to the fourth feature, in the cable 1, 1B, 1C described in any one of the first feature to the third feature, the planar conductor 52 is formed by vapor deposition on the base material 51.

According to the fifth feature, in the cable 1 described in any one of the first feature to the third feature, the planar conductor 53 is bonded to the base material 51.

According to the sixth feature, in the cable 1, 1B, 1C as described in the first feature, the wire bundle 10 includes at least three wires 2 to 4 bundled together, wherein a filler 7 is disposed between the binder member 5, 5A and the at least three wires 2 to 4, wherein a shape of the binder member 5, 5A in a cross-section perpendicular to a longitudinal direction of the wire bundle 10 is circularized by the filler 7.

According to the seventh feature, in the cable 1, 1B, 1C as described in the sixth feature, the wire bundle 10 includes a plurality of large diameter wires (first and second wires 2, 3) and at least one multi-core wire 4 including a plurality of small diameter wires (signal wires 41, 42) whose outer diameters are smaller than the plurality of large diameter wires 2, 3, collectively covered by a sheath (inner sheath 43), and wherein respective outer diameters of the plurality of large diameter wires 2, 3 and an outer diameter of the at least one multi-core wire 4 are substantially the same.

According to the eighth feature, the cable 1, 1B, 1C as described in the first feature, further includes a linear conductor 6 electrically connected to the planar conductor 52, 53 at one terminal in a cable longitudinal direction (longitudinal direction of the cable 1, 1B, 1C), wherein the linear conductor 6 is arranged together with the plurality of wires 2 to 4 inside the binder member 5, 5A.

According to the ninth feature, in the cable 1, 1B as described in the eighth feature, the linear conductor 6 has lower bending endurance than the plurality of wires 2 to 4.

According to the tenth feature, a damage detection device 11, 12 includes a binder member 5, 5A spirally wound around an outer circumference of a wire bundle 10 including a plurality of wires 2 to 4 bundled together and including a base material 51 composed of a band-shaped insulating material and a planar conductor 52, 53 provided on one side 51a of the base material 51 along a longitudinal direction of the base material 51, and a damage detection circuit 110, 120 that detects an occurrence of damage when the planar conductor 52, 53 is damaged.

The above description of the embodiments and modified examples of the invention does not limit the invention as claimed. It should also be noted that not all of the combinations of features described in the embodiments and modified examples are essential to the means for solving the problems of the invention. In addition, the invention can be implemented by modifying it as appropriate to the extent that it does not depart from the intent of the invention, for example, the invention can be implemented by modifying it as follows.

In the above embodiments, the case in which the third wire 4, which is a multi-core wire, has a plurality of signal wires 41, 42 as small diameter wires was described. The plurality of small diameter wires constituting the multi-core wire may be used as power supply lines to supply an operating power source to a target device. The target devices include, for example, an active suspension device with variable damping force and an air pressure sensing device that detects the air pressure of tires.

In the above embodiments, the first and second wires 2 and 3 are used as power supply lines to supply operating power to the electric parking brake device, and the signal wires 41 and 42 of the third wire 4 are used to transmit the output signal of the wheel speed sensor. However, the application of the first to third wires 2 to 4 is not limited thereto. For example, the first wire 2 and the second wire 3 may be used as power supply lines for supplying operating power to the electric brake device that brakes the rotation of the wheels while the vehicle is running, and the signal wires 41 and 42 of the third wire 4 may be used to transmit control signals for controlling the electric brake device.

In the above embodiments, the case in which three wires (first to third wires 2 to 4) are bundled together to form the wire bundle 10 was described, but this is not limited to the case in which the number of wires may be two or four or more.

In the above embodiments, the case of detecting a breakage of the planar conductor 52 by applying a DC current to the planar conductor 52 was described, but it is not limited to this case. For example, a pulse signal may be input to the planar conductor 52, and the detection of a breakage in the planar conductor 52 may be confirmed by checking whether this signal returns via the linear conductor 6. Alternatively, a signal containing an AC component may be input to the planar conductor 52, and the detection of a breakage in the planar conductor 52 may be confirmed by detecting a response signal using a reflection method or transmission method.

In the above embodiment, the case where cable 1 is installed in a vehicle was described, but this is not limited to this, and the cable 1 may also be used in industrial machinery such as robots and machine tools.

1. A cable, comprising:
a wire bundle comprising a plurality of wires bundled together;
a binder member spirally wound around an outer circumference of the wire bundle; and
a sheath covering the binder member,
wherein the binder member includes a base material comprising a band-shaped insulating material, and a planar conductor provided on one side of the base material along a longitudinal direction of the base material, and
wherein the binder member is overlappedly wound around the outer circumference of the wire bundle in such a manner that ends in a width direction of the base material overlap each other.

2. The cable, according to claim 1, wherein the planar conductor is provided on a sheath side in the base material.

3. The cable, according to claim 1, wherein the binder member comprises a width of the planar conductor in the width direction of the base material narrower than a width of the base material, and
wherein the ends in the width direction of the base material overlap each other in contact.

4. The cable, according to claim 1, wherein the planar conductor is formed by vapor deposition on the base material.

5. The cable, according to claim 1, wherein the planar conductor is bonded to the base material.

6. The cable, according to claim 1, wherein the wire bundle comprises at least three wires bundled together, wherein a filler is disposed between the binder member and the at least three wires,
wherein a shape of the binder member in a cross-section perpendicular to a longitudinal direction of the wire bundle is circularized by the filler.

7. The cable, according to claim 6, wherein the wire bundle comprises a plurality of large diameter wires and at least one multi-core wire comprising a plurality of small diameter wires whose outer diameters are smaller than the plurality of large diameter wires, collectively covered by a sheath, and
wherein respective outer diameters of the plurality of large diameter wires and an outer diameter of the at least one multi-core wire are substantially the same.

8. The cable, according to claim 1, further comprising:
a linear conductor electrically connected to the planar conductor at one terminal in a cable longitudinal direction, wherein the linear conductor is arranged together with the plurality of wires inside the binder member.

9. The cable, according to claim 8, wherein the linear conductor comprises lower bending endurance than the plurality of wires.

10. A damage detection device, comprising:
a binder member spirally wound around an outer circumference of a wire bundle comprising a plurality of wires bundled together and a base material comprising a band-shaped insulating material and a planar conductor provided on one side of the base material along a longitudinal direction of the base material; and
a damage detection circuit that detects an occurrence of damage when the planar conductor is damaged.
